(19) United States
(12) Patent Application Publication
(10) Pub. No.: US 2009/0160396 A1
(43) Pub. Date: Jun. 25, 2009

(54) Charging device receiving light from diverse sources

(75) Inventors: Ruey-Jong Shyu, Taoyuan Hsien (TW); Kuan-Liang Chen, Taoyuan Hsien (TW); Liang-Jyi Chen, Taoyuan Hsien (TW); Ming-Jyh Sun, Taoyuan Hsien (TW)

Correspondence Address: BACON & THOMAS, PLLC, 625 SLATERS LANE, FOURTH FLOOR, ALEXANDRIA, VA, 22314-1176, US

(73) Assignee: J Touch Corporation, Taoyuan Hsien (TW)

(21) Appl. No.: 12/289,990

(22) Filed: Nov. 10, 2008

(30) Foreign Application Priority Data
Dec. 19, 2007 (TW) 96148590
Feb. 1, 2008 (TW) 97103907

(51) Int. Cl. H02J 7/00; H01L 31/042; H01L 31/045

(52) U.S. Cl. 320/101; 136/244; 136/245

(57) ABSTRACT

A charging device that receives light from diverse sources includes at least a solar cell that receives light from diverse sources to generate a voltage source, a charging circuit module connected with the solar cell to boost the voltage of the voltage source, and a connector connected with the charging circuit module. Such a design enables the present invention to charge a mobile phone or rechargeable battery by receiving the light radiated from the indoor light kits or sunlight.

### BACKGROUND OF THE INVENTION

1. Field of the Invention

The present invention relates to a charging device, more particularly, a charging device that receives light from diverse sources.

2. Description of the Related Art

As mobile phone, a popular tool for communication, has been equipped with more and more new functions, it inevitably requires higher power consumption, and thus the battery life becomes unbearably short for the user. Currently, the battery life of the shipped Li-ion cell is still insufficient to support satisfactory standby time and talk time, so one will always get a charger whenever s/he purchases a new mobile phone. In addition, some use battery power supplies to charge mobile phones, but they are neither economical nor environmental friendly as new batteries are required on a regular basis. Solar cell, normally a silicon crystal solar cell or a thin film solar cell, is another option, but it is inconvenient as well because it conducts the charging task only when sufficient sunlight is available.

There is a new-type dye-sensitized solar cell (DSSC) that features high conversion efficiency under dim sunlight or indoor lighting. After the DSSC receives light, electrons will be released from the dye molecules and then transmitted to the TCO glass via the optical semiconductor oxide to generate a voltage source and further supply an electric current.

A dye-sensitized solar cell (DSSC) converts light energy into electrical energy via a photoelectrochemical energy conversion mechanism. Its operation principle is different from that of a silicon crystal solar cell or a thin film solar cell which is made of silicon. A DSSC generally consists of two pieces of transparent conducting oxide (TCO) glasses: one TCO glass is an electrode on which a layer of semiconductor oxide, such as a nanocrystalline titanium oxide (TiO2) layer, is deposited; the other is a counterelectrode which has platinum thin film on it. In between the two electrodes, there are electrolyte and dye molecules adsorbed on the TiO2 layer. After the two electrodes are properly packaged and sealed, a DSSC is completed. When sunlight irradiates a DSSC, the dye molecules release electrons that pass through the TiO2 layer and TCO layer to an outer circuit to generate electricity. The electrons then go to the counterelectrode, where they undergo the electrocatalytic activity of the platinum and redox reaction of the electrolyte, and return to the dye molecules to complete the cycle. A DSSC absorbs solar energy within the range of visible light spectrum. In addition to absorbing solar radiation in an outdoor environment to generate electricity, a DSSC can also generate electricity at a lower light intensity either in an indoor environment or under lighting devices; therefore, it can be used in both outdoor and indoor environments. Moreover, a DSSC uses more common materials, such as conducting glass, titanium oxide, platinum, electrolyte and dye. Furthermore, manufacturing a DSSC does not require expensive equipments, such as PECVD equipment, but requires only inexpensive equipments like screen printers, sintering ovens, etc. Therefore, DSSCs are advantageous in reducing manufacturing cost compared to silicon-based solar cells. A DSSC can be of various colors depending on the dyes it uses, and it can also be made on flexible substrates. The DSSC is a new-generation solar cell of multiple applications.

### SUMMARY OF THE INVENTION

The object of the present invention is to combine a DSSC that can generate electricity in both indoor and outdoor environments with a charging circuit module and an electricity storage element to create a charging device which can charge a mobile phone or the rechargeable battery thereof under indoor lighting or sunlight.

Another object of the present invention is to provide a charging device that receives light from diverse sources.

The charging device that receives light from diverse sources of the first embodiment of the present invention includes a DSSC module comprising at least a DSSC, a charging circuit module and a connector. In addition, the second and third embodiments of the present invention that demonstrate the DSSC module with a pivotal structure and in a push-pull design respectively are provided to enlarge the light receiving area, increase the portability and reduce the size of the DSSC module. The DSSC module with a pivotal structure is foldable while the one in a push-pull design allows one cell to be stored in the other.

Moreover, the main body of another embodiment of the present invention comprises a pyramid which is set on a trapezoid base to form a larger pyramid and pivots on it through a pivotal structure. The four surfaces of the trapezoid base are disposed with a plurality of DSSCs while the charging base is set on the flat of the trapezoid base.

Furthermore, the main body of another embodiment of the present invention is a table, on top of which a DSSC is installed, or the tabletop itself is a DSSC.

The foregoing embodiments further include an electricity storage element connected with the charging circuit module to store electricity provided by the charging circuit module. Moreover, the electricity storage module is connected with the charging base.

Consequently, the present invention provides a novel charging device that can charge a mobile phone through receiving light from diverse sources, including sunlight and the dimmer light radiated from indoor illuminators.

### BRIEF DESCRIPTION OF THE DRAWINGS

FIG. 1 shows the conventional way of charging a mobile phone;

FIG. 2 shows how a prior art solar cell is charged;

FIG. 3 is a 3-dimensional view of a charging device that receives light from diverse sources, according to the first embodiment of the present invention;

FIG. 4 is a block drawing of a charging circuit module of the present invention;

FIG. 5 is a circuit arrangement drawing of the charging circuit module of the present invention;

FIG. 6 shows the structure of a DSSC of the present invention;

FIG. 7 is a 3-dimensional view of a charging device that receives light from diverse sources, according to the second embodiment of the present invention;

FIG. 8 is an exploded view of a charging device that receives light from diverse sources, according to the second embodiment of the present invention;

FIG. 9 is a 3-dimensional view of a charging device that receives light from diverse sources, according to the third embodiment of the present invention;

FIG. 10 is an exploded view of a charging device that receives light from diverse sources, according to the third embodiment of the present invention;

FIG. 11 is a schematic cross-sectional view of a third cell, according to the third embodiment of the present invention;

FIG. 12 is a 3-dimensional view of a fourth cell, according to the third embodiment of the present invention;

FIG. 13 is a 3-dimensional view of a charging device that receives light from diverse sources, according to the fourth embodiment of the present invention;

FIG. 14 is a block diagram of a charging device that receives light from diverse sources, according to the fourth embodiment of the present invention;

FIG. 15 is a 3-dimensional view of a charging device that receives light from diverse sources, according to the fifth embodiment of the present invention;

FIG. 16 is a block diagram of a charging device that receives light from diverse sources, according to the fifth embodiment of the present invention;

FIG. 17 is a 3-dimensional view of a charging device that receives light from diverse sources, according to the sixth embodiment of the present invention;

FIG. 18 is an exploded view of a charging device that receives light from diverse sources, according to the sixth embodiment of the present invention;

FIG. 19 is a 3-dimensional view of a charging device that receives light from diverse sources, according to the seventh embodiment of the present invention;

FIG. 20 is a 3-dimensional view of a charging device that receives light from diverse sources, according to the eighth embodiment of the present invention;

FIG. 21 is a 3-dimensional view of a charging device that receives light from diverse sources, according to the ninth embodiment of the present invention;

FIG. 22 is a state view of a charging device that receives light from diverse sources, according to the ninth embodiment of the present invention;

FIG. 23 is a 3-dimensional view of a charging device that receives light from diverse sources, according to the tenth embodiment of the present embodiment;

FIG. 24 is a 3-dimensional view of a charging device that receives light from diverse sources, according to the eleventh embodiment of the present invention; and

FIG. 25 is a 3-dimensional view of a charging device that receives light from diverse sources, according to the twelfth embodiment of the present invention.

### DETAILED DESCRIPTION OF THE PREFERRED EMBODIMENTS

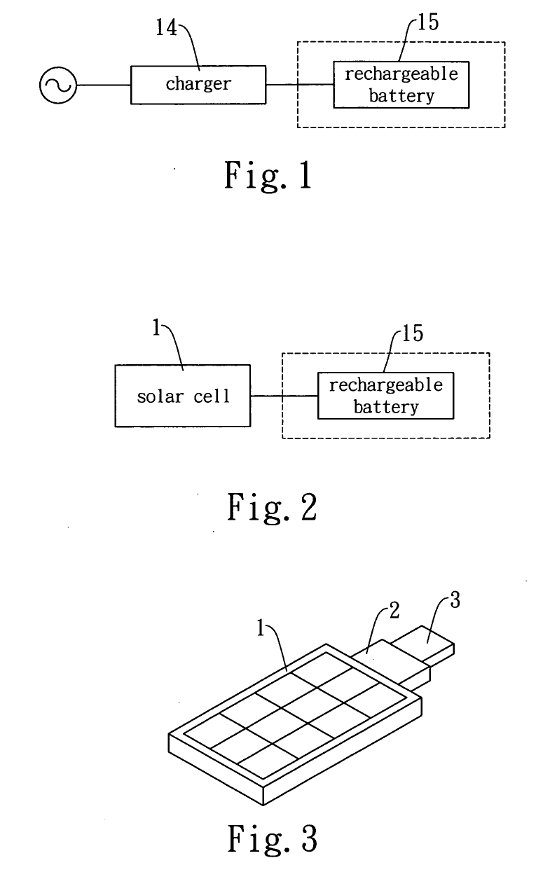

FIG. 1 shows the conventional way of charging a mobile phone whose rechargeable battery 15 is charged by an external charger 14. FIG. 2 shows how a prior art solar cell is charged. In this case, the solar cell 1 receives an external light source to charge the rechargeable battery 15. The DSSC of the present invention can charge devices, such as a mobile phone, PDA and smart phone, in both indoor and outdoor environments.

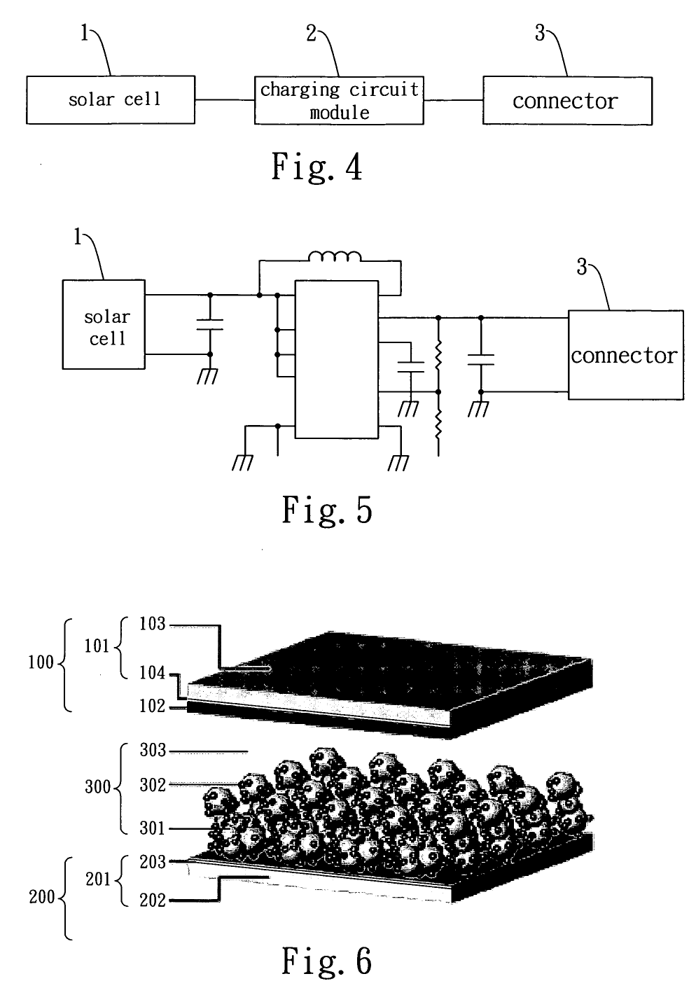

FIG. 3, FIG. 4 and FIG. 5 show a 3-dimensional view of a charging device that receives light from diverse sources, a block drawing of the charging circuit module and a circuit arrangement drawing of the charging circuit module respectively, according to the first embodiment of the present invention. The charging device that receives light from diverse sources of the present invention comprises at least a solar cell 1 that receives light from diverse sources, including the light radiated from indoor illuminators, to generate a voltage source, a charging circuit module 2 and a connector 3. The light source could be sunlight, fluorescent lamp, indoor illuminator etc. The solar cell 1 could be a DSSC or other solar cells with equivalent efficiency. The solar cell 1 of the first embodiment is a DSSC but not limited to it as the spirit of the present invention can be applied to other solar cells. Referring to FIG. 6, the DSSC comprises a first electrode 100, a second electrode 200, and a nano layer 300 set between the two electrodes. The first electrode 100 includes a first TCO glass 101 comprising a first glass 103 and a first transparent conductive oxide 104, and a platinum catalyst layer 102 adhered to the first transparent conductive oxide 104. The second electrode 200 includes a second TCO glass 201 comprising a second glass 202 and a second transparent conductive oxide 203. The nano layer 300 includes an optical semiconductor oxide 301, which could be a titanium dioxide, zinc oxide or other oxides with equivalent efficiency, a plurality of dyes 302 attached to the optical semiconductor oxide 301 and an electrolyte 303. The nano layer 300 enables the DSSC to convert solar power into electricity. No further discussion on how a DSSC functions will be made as it involves prior knowledge.

The charging circuit module 2 is connected with the solar cell 1 to boost the voltage of the voltage source to provide a mobile phone electricity. A voltage boost circuit included in the charging circuit module 2 can increase the voltage of the voltage source when receiving electricity outputted from the solar cell 1, and then the voltage will be outputted from the connector 3 connected with the charging circuit module 2. The connector 3 is a USB connector or D.C. connector so that it can be connected with different mobile phones or devices easily.

Therefore, the first embodiment of the present invention demonstrates that the DSSC can absorb both sunlight and the light radiated from an indoor illuminator, such as a fluorescent lamp or table lamp, to convert solar energy into electricity to charge a mobile phone. Among solar cells whose sensitivity to indoor lighting varies, the DSSC has better efficiency and thus is suitable to be used to charge a mobile phone. As shown in Diagram 1, a mobile phone generally requires 1068 mW power consumption under regular operation while only 2.3 mW power consumption is required under standby mode.

Diagram 1 Power Consumption Comparison
between Mobile Phone and PDA.

| Mobile | Power | | Power |
|---|---|---|---|
| Phone (2-inch) | Consumption (mW) | PDA | Consumption |
| Phone Mode/ | 810/2 | In Operation | 210 |
| Standby Mode | | | |
| Backlight Module | 250/0 | Backlight | 370 |
| | | Module | |
| Main/ | 8/0.3 | IC Module | 60 |
| Sub IC Module | | | |
| Total | 1,068/2.3 | Total | 640 |

Source: Topology Research Institute (TRI), April, 2006

Diagram 2 and Diagram 3 show test data on voltage/current of a DSSC under indoor lighting.

According to Diagram 2 and Diagram 3, a voltage of approximately 0.5˜0.6V will be generated under 300 to 5300 lux, and the strength of an electric current is in connection with illumination and the light receiving area of a DSSC. For example, a current of approximately 25 mA, which is sufficient for charging a mobile phone, will be generated under 5300 lux. Thus, with suitable design, a DSSC can be slipped into one's pocket easily while s/he is traveling.

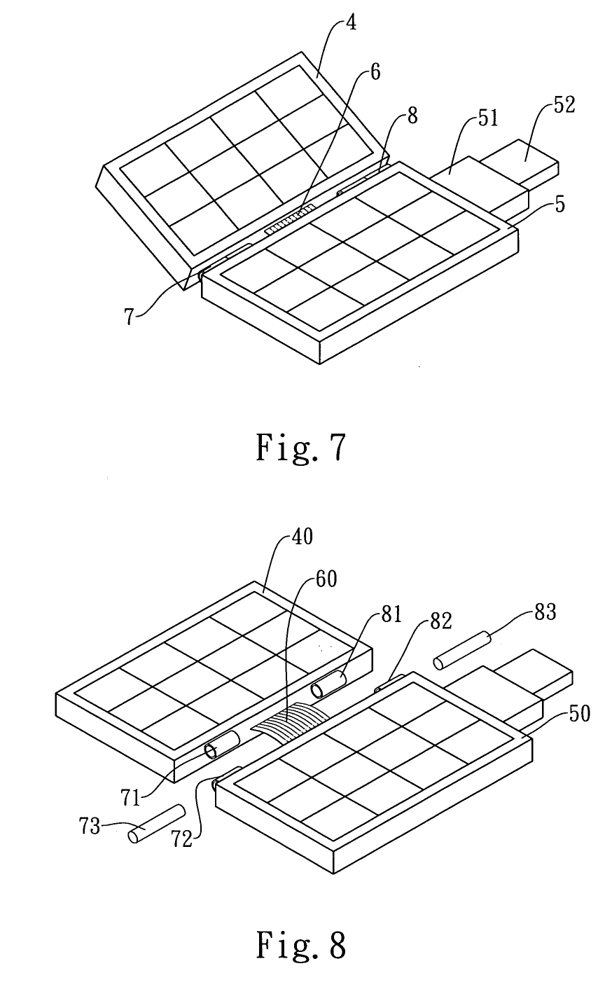

FIG. 7 and FIG. 8 show a 3-dimensional view and an exploded view of a charging device that receives light from diverse sources respectively, according to the second embodiment of the present invention. In this embodiment, the DSSC module includes a first cell 4 and a second cell 5. The two cells are connected by a first leading wire 6 so that the current can flow from the first cell 4 to the second cell 5 connected with a charging circuit module 51 that joints a connector 52. The mobile phone connected with the connector 52 will then receive the current after the current passes through the voltage boost circuit. Moreover, the DSSC module is foldable and easy to be stored as the corresponding sides of the first cell 4 and the second cell 5 are connected by pivot 7 and pivot 8. The pivot that includes a first housing 71 and a second housing 81 is set on one side of the first cell 4. The pivot that includes a third housing 72 and a fourth housing 82 is set on one side of the second cell 5. Moreover, the third housing 72 and fourth housing 82 with respect to the first housing 71 and second housing 81 are arranged at relatively outer sides. A first shaft 73 is inserted into the first housing 71 and the third housing 72 while a second shaft 83 is inserted into the second housing 81 and the fourth housing 82. Therefore, the DSSC module that comprises the first cell 4 and the second cell 5 is foldable because of pivot 7 and pivot 8. The second embodiment demonstrates a DSSC module in a double-foldable design but is not limited hereto, that is, it can be designed as a double, triple or multiple-foldable charging device.

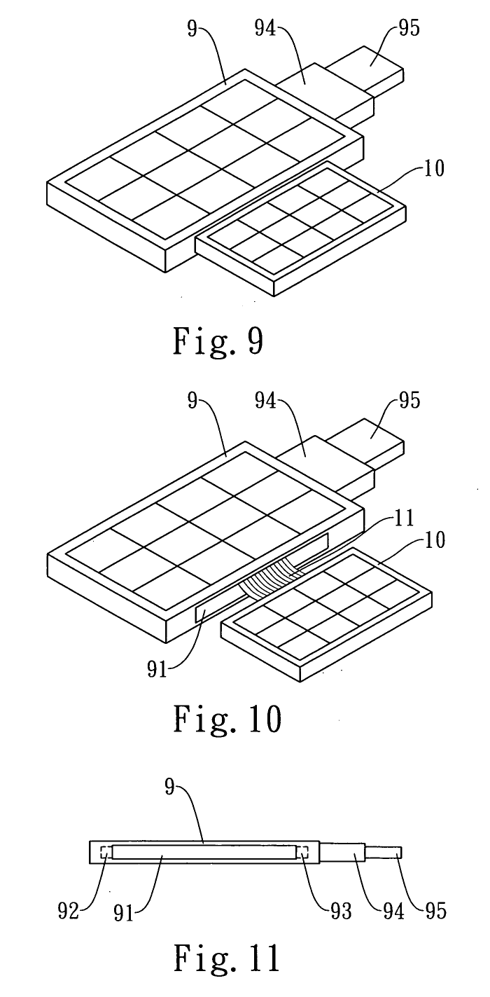

FIG. 9 and FIG. 10 show a 3-dimensional view and an exploded view of a charging device that receives light from diverse sources respectively, according to the third embodiment of the present invention. In this embodiment, the DSSC module includes a third cell 9 connected with a charging circuit module 94 that joints a connector 95, and a fourth cell 10. The two cells are connected by a second leading wire 11 so that the current can flow from the fourth cell 10 to the third cell 9 with the connector 95 to charge a mobile phone. In addition, the third cell 9 has a storage stack 91 in which the fourth cell 10 can be stored.

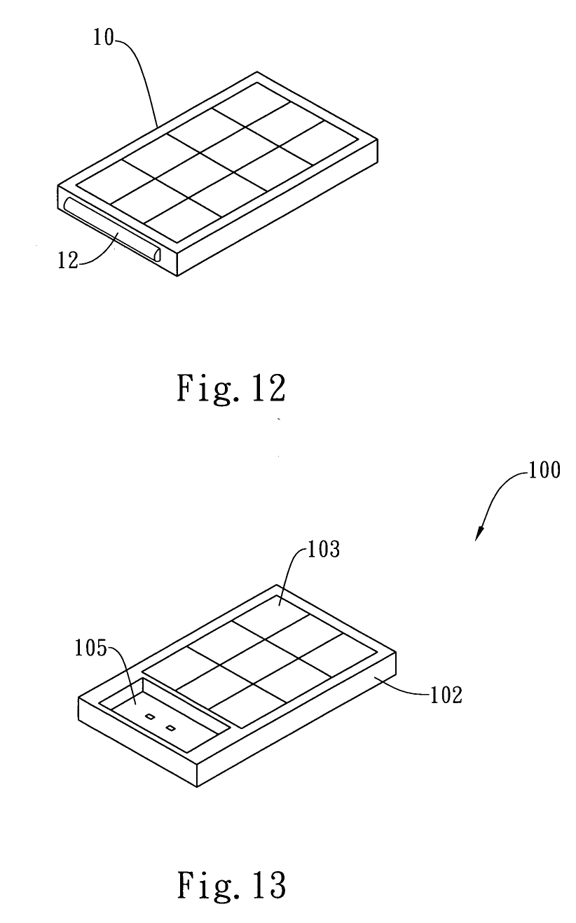

FIG. 11 and FIG. 12 show a schematic cross-sectional view of a third cell and a 3-dimensional view of a fourth cell respectively, according to the third embodiment of the present invention. The storage stack 91 of the third cell 9 is of square shape, and a first rail groove 92 and a second rail groove 93 are cut across both sides of the stack. Moreover, a first rail protrusion 12 and a second rail protrusion (not shown in the drawing) that fit the rail grooves are correspondingly set on both sides of the fourth cell 10, allowing the fourth cell 10 to be slid into/out of the storage stack 91.

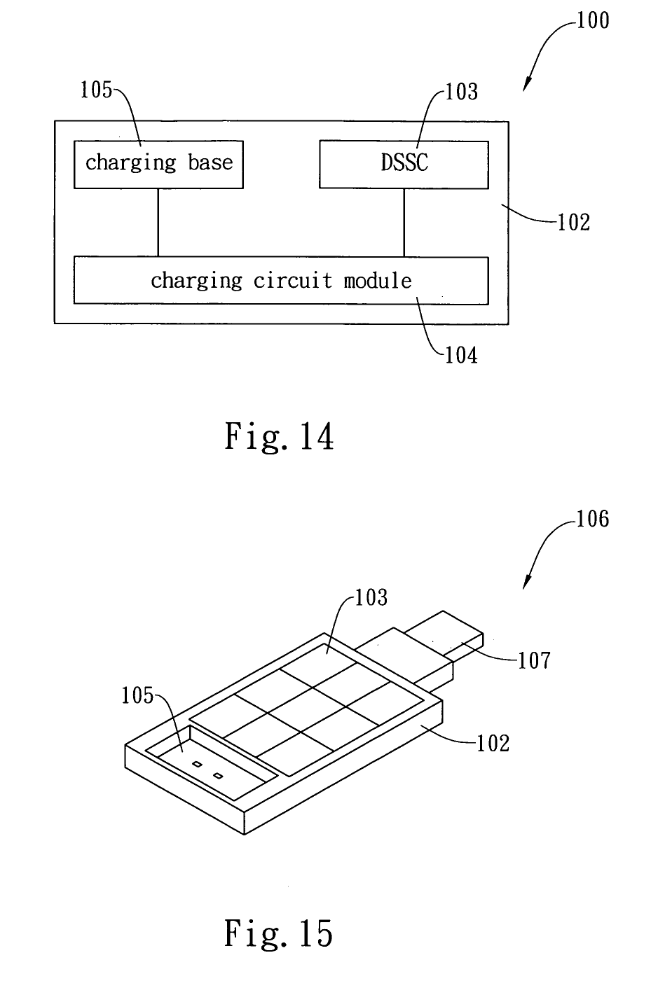

FIG. 13 and FIG. 14 show a 3-dimensional view and a block diagram of a charging device that receives light from diverse sources respectively, according to the fourth embodiment of the present invention. In this embodiment, the charging device 100 that receives light from diverse sources includes a main body 102, a DSSC module 103 comprising at least a DSSC which is disposed on the main body 102 and can receive light from diverse sources to generate a voltage source, a charging circuit module 104 set inside the main body 102 and connected with the DSSC 103 to boost the voltage of the voltage source, and a charging base 105 set on the main body 102 and connected with the charging circuit module 104 for charging a specific device, such as a rechargeable battery or mobile phone.

In this embodiment, the DSSC 103 module is the same as those described in the foregoing embodiments while the charging circuit module 104 is integrated with a voltage boost circuit to increase the voltage of the voltage source.

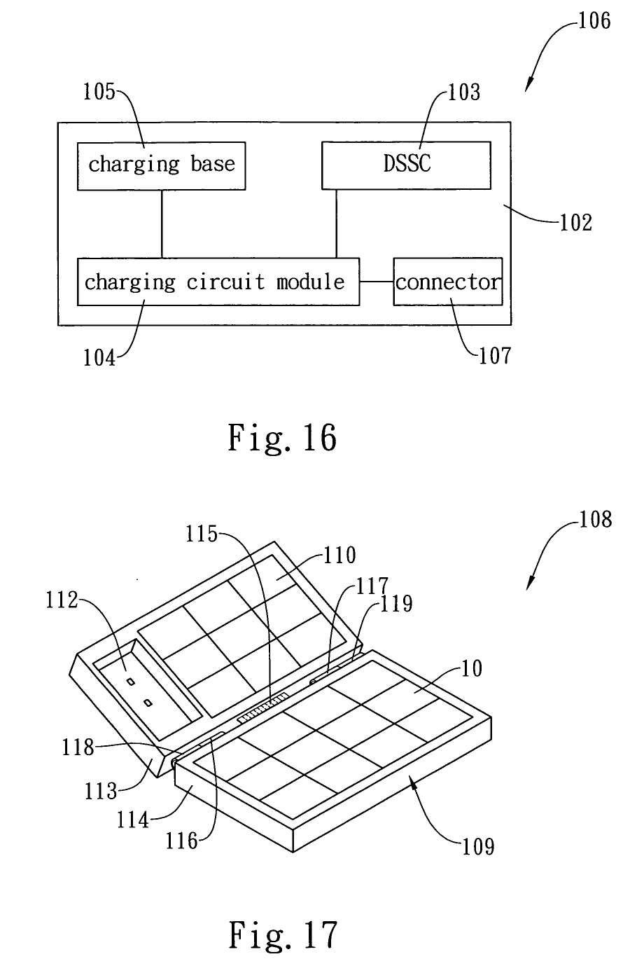

FIG. 15 and FIG. 16 show a 3-dimensional view and a block diagram of a charging device that receives light from diverse sources respectively, according to the fifth embodiment of the present invention. In this embodiment, the charging device 106 that receives light from diverse sources includes a main body 102, a DSSC module 103 comprising at least a DSSC which is set on the main body 102 and can receive light from diverse sources to generate a voltage source, a charging circuit module 104 set inside the main body 102 and connected with the DSSC 103 to boost the voltage of the voltage source, a charging base 105 set on the main body 102 and connected with the charging circuit module 104 for charging a specific device, such as a rechargeable battery or mobile phone, and a connector 107 connected with the charging circuit module 104. The connector 107 is a USB connector or D.C. connector so that it can be connected with mobile phones or other devices easily.

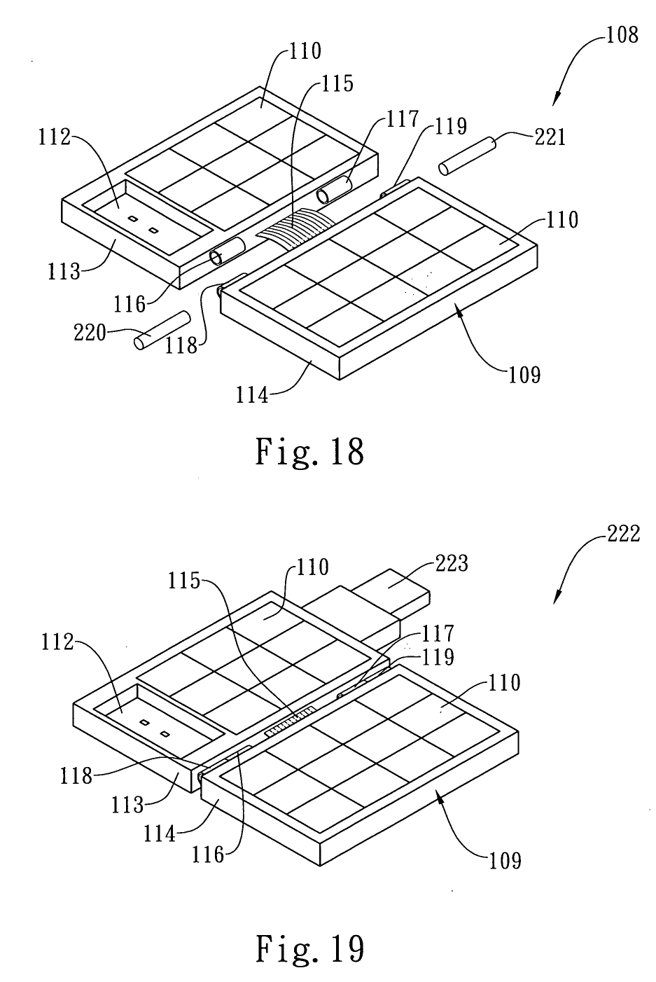

FIG. 17 and FIG. 18 show a 3-dimensional view and an exploded view of a charging device that receives light from diverse sources respectively, according to the sixth embodiment of the present invention. In this embodiment, the charging device 108 that receives light from diverse sources comprises a main body 109, a DSSC module 110 comprising at least a DSSC which is set on the main body 109 and can receive light from diverse sources to generate a voltage source, a charging circuit module (not shown in the drawing) set inside the main body 109 and connected with the DSSC 110 to boost the voltage of the voltage source, and a charging base 112 set on the main body 109 and connected with the charging circuit module for charging a specific device, such as a rechargeable battery or mobile phone.

The main body 109 that includes a first panel 113 and a second panel 114 is foldable because of the pivotal structure that connects the two panels. A plurality of cells comprised in the DSSC module 110 are disposed on the first panel 113 and the second panel 114 while the charging base 112 is set on the first panel 113.

The DSSC module 110 comprises at least two cells, including a first cell set on the first panel 113 and a second cell set on the second panel 114, and the two cells are connected by a third leading wire 115.

The corresponding sides of the first panel 113 and second panel 114 are connected by two pivots. The pivot that includes a first housing 116 and a second housing 117 is set on one side of the first panel 113 while the pivot that includes a third housing 118 and a fourth housing 119 is set on one side of the second panel 114. Moreover, the third housing 118 and fourth housing 119 with respect to the first housing 116 and the second housing 117 are arranged at relatively outer sides. A first shaft 220 is inserted into the first housing 116 and the third housing 118 while a second shaft 221 is inserted into the second housing 117 and the fourth housing 119. Consequently, the main body 109 that includes a first panel 113 and a second panel 114 is foldable because of the pivotal structure that connects the two panels.

FIG. 19 is a 3-dimensional view of a charging device that receives light from diverse sources, according to the seventh embodiment of the present invention. In this embodiment, the charging device 222 that receives light from diverse sources has an additional connector 223 connected with the charging circuit module (not shown in the drawing) than the charging device 108 demonstrated in the sixth embodiment. The connector 223 is a USB connector or D.C. connector.

In addition, the charging devices demonstrated in the first to sixth embodiments further include an electricity storage element (not shown in the drawing) that is connected with the charging circuit module to store electricity provided by the charging circuit module.

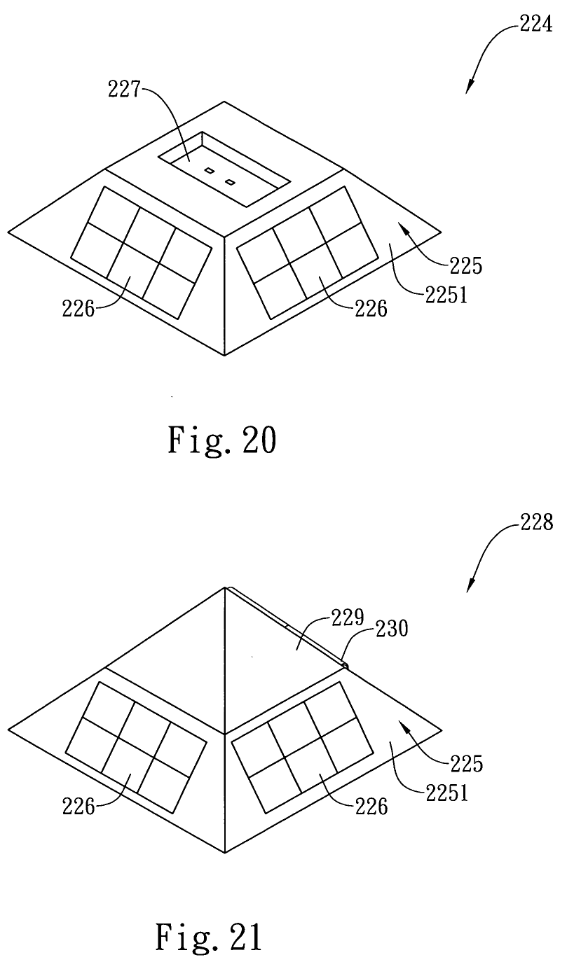

FIG. 20 is a 3-dimensional view of a charging device that receives light from diverse sources, according to the eighth embodiment of the present invention. In this embodiment, the charging device 224 that receives light from diverse sources includes a main body 225, a DSSC module 226 comprising at least a DSSC which is set on the main body 225 and can receive light from diverse sources to generate a voltage source, a charging circuit module (not shown in the drawing) set inside the main body 225 and connected with the DSSC module 226 to boost the voltage of the voltage source, and a charging base 227 set on the main body 225 and connected with the charging circuit module for charging a specific device, such as a rechargeable battery or mobile phone.

The main body 225 comprises a trapezoid base 2251 whose four surfaces are disposed with a plurality of cells included in the DSSC module 226, and the charging base 227 is set on the flat of the trapezoid base 2251.

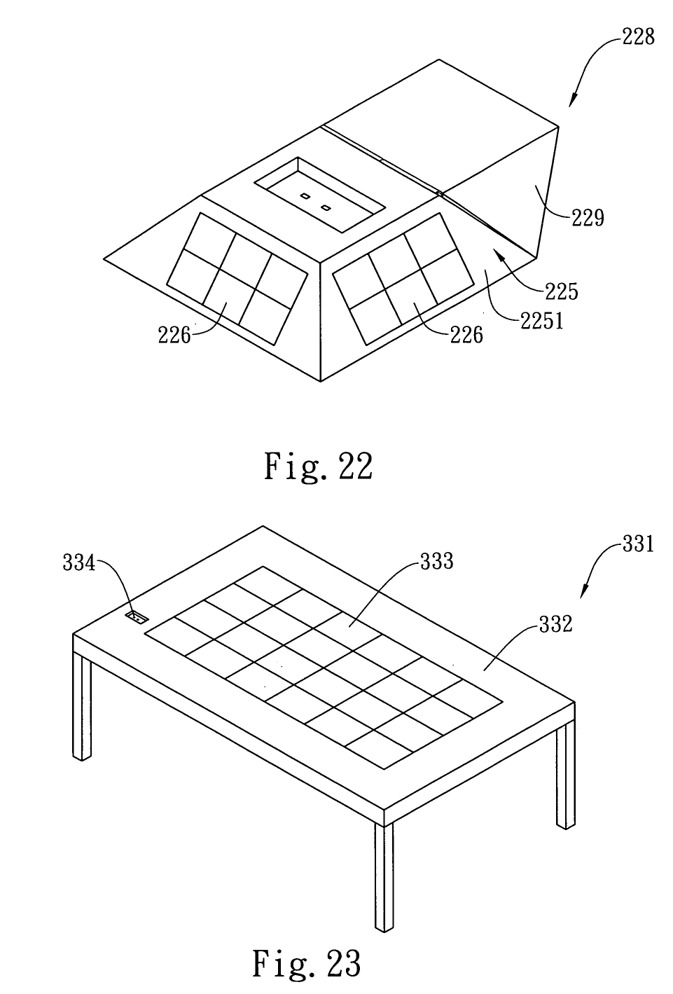

FIG. 21 and FIG. 22 show a 3-dimensional view and a state view of a charging device that receives light from diverse sources, according to the ninth embodiment of the present invention. In this embodiment, the charging device 228 that receives light from diverse sources has an additional pyramid 229 than the charging device 224 demonstrated in the eighth embodiment. The pyramid 229 is set on the trapezoid base 2251 to form a larger pyramid and pivots on the trapezoid base 2251 through a pivotal structure. The corresponding sides of the trapezoid base 2251 and the pyramid 229 are connected by a pivot 230. In addition, the charging devices demonstrated in the seventh and eighth embodiments further include an electricity storage element (not shown in the drawing) that is connected with the charging circuit module to store electricity provided by the charging circuit module.

FIG. 23 is a 3-dimensional view of a charging device that receives light from diverse sources, according to the tenth embodiment of the present invention. In this embodiment, the charging device 331 that receives light from diverse sources includes a main body 332, a DSSC module 333 comprising at least a DSSC which is set on the main body 332 and can receive light from diverse sources to generate a voltage source, a charging circuit module (not shown in the drawing) set inside the main body 332 and connected with the DSSC module 333 to boost the voltage of the voltage source, and a charging base 334 set on the main body 332 and connected with the charging circuit module for charging a specific device, such as a rechargeable battery or mobile phone.

The main body 332 is a table with four legs, and the DSSC module comprising at least a DSSC is disposed on the tabletop.

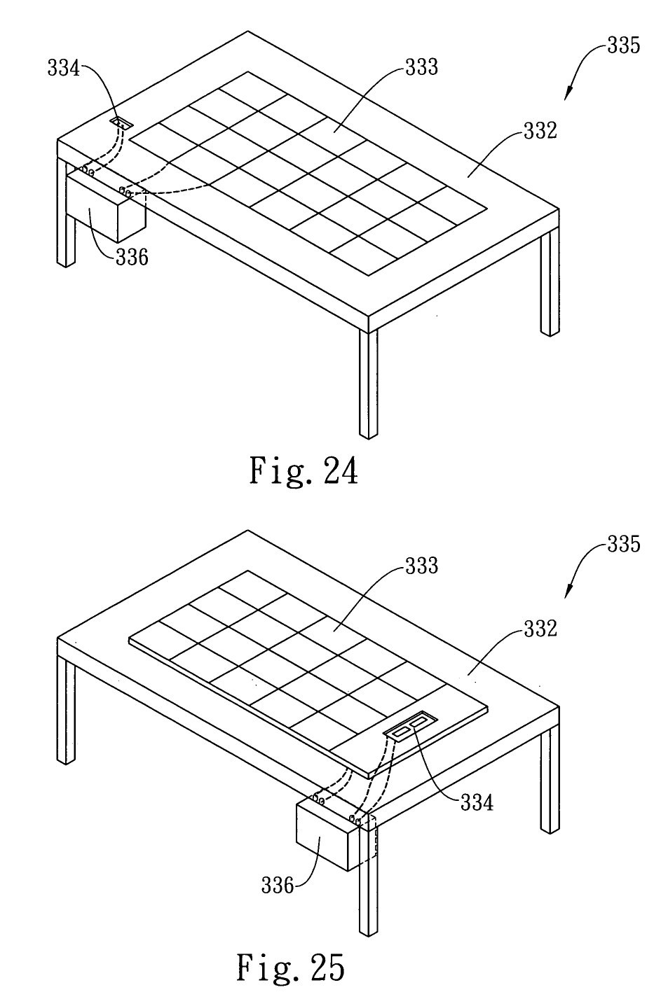

FIG. 24 is a 3-dimensional view of a charging device that receives light from diverse sources, according to the eleventh embodiment of the present invention. In this embodiment, the charging device 335 that receives light from diverse sources has an additional electricity storage element 336 than the charging device 331 demonstrated in the tenth embodiment. The electricity storage element 336 is connected with the charging circuit module to store electricity provided by the charging circuit module. Moreover, the electricity storage element 336 is connected with the charging base 334.

FIG. 25 is a 3-dimensional view of a charging device that receives light from diverse sources, according to the twelfth embodiment of the present invention. The only difference between this embodiment and the tenth embodiment is that the tabletop demonstrated in this embodiment is a DSSC module.

In sum, the charging device that receives light from diverse source of the present invention is a novel device that can charge a mobile phone by receiving sunlight or the light radiated from indoor illuminators.

What is claimed is:

1. A charging device that receives light from diverse sources, including:
a solar cell module comprising at least a solar cell that receives light from diverse sources to generate a voltage source;
a charging circuit module connected with said solar cell to boost the voltage of said voltage source; and
a connector that joints said charging circuit module.

2. The charging device that receives light from diverse sources according to claim 1, wherein said solar cell is a DSSC.

3. The charging device that receives light from diverse sources according to claim 2, wherein said DSSC includes a first electrode that comprises a first TCO glass comprising a first glass and a first transparent conductive oxide and a platinum catalyst layer attached to said first transparent conductive oxide, a second electrode that includes a second TCO glass comprising a second glass and a second transparent conductive oxide, and a nano layer that comprises an optical semiconductor oxide, a plurality of dyes attached to said optical semiconductor oxide and an electrolyte; and wherein said nano layer is set between two said electrodes.

4. The charging device that receives light from diverse sources according to claim 1, wherein said charging circuit module includes a voltage boost circuit to increase the voltage of said voltage source of said DSSC.

5. The charging device that receives light from diverse sources according to claim 1, wherein said connector is a USB connector or D.C. connector.

6. The charging device that receives light from diverse sources according to claim 1, wherein said DSSC module comprises at least two cells including a first cell and a second cell connected by a first leading wire.

7. The charging device that receives light from diverse sources according to claim 6, wherein said DSSC module is foldable as the corresponding sides of said first cell and said second cell are connected by a pivotal structure.

8. The charging device that receives light from diverse sources according to claim 7, wherein a pivot that includes a first housing and a second housing is set on one side of said first cell while a pivot that includes a third housing and a fourth housing is set on one side of said second cell; wherein said third housing and said fourth housing with respect to said first housing and said second housing are arranged at relatively outer sides; and wherein a first shaft is inserted into said first housing and said third housing while a second shaft is inserted into said second housing and said fourth housing, thus said DSSC module is foldable because of said pivotal structure.

9. The charging device that receives light from diverse sources according to claim 1, wherein said DSSC module comprises at least two cells including a third cell and a fourth cell connected by a second leading wire; and wherein said third cell has a storage stack in which said fourth cell can be stored.

10. The charging device that receives light from diverse sources according to claim 9, wherein said storage stack is of rectangular shape, and a first rail groove and a second rail groove are cut across its both sides; and wherein a first rail protrusion and a second rail protrusion that fit said rail grooves are set on both sides of said fourth cell, allowing said fourth cell to be slid into/out of said storage stack.

11. The charging device that receives light from diverse sources according to claim 1, further including an electricity storage element connected to said charging circuit module to store electricity provided by said charging circuit module.

12. A charging device that receives light from diverse sources, including:
a main body;
a solar cell module comprising at least a solar cell which is set on said main body and can receive light from diverse sources to generate a voltage source;
a charging circuit module set inside said main body and connected with said solar cell to boost the voltage of said voltage source; and
a charging base set on said main body and connected with said charging circuit module for charging a specific device.

13. The charging device that receives light from diverse sources according to claim 12, wherein said solar cell is a DSSC.

14. The charging device that receives light from diverse sources according to claim 12, wherein said main body that includes a first panel and a second panel is foldable because two said panels are connected by a pivotal structure; wherein said DSSC module is disposed on said first panel and said second panel; and wherein said cells are connected by a third leading wire.

15. The charging device that receives light from diverse sources according to claim 14, wherein said charging base is set on said first panel or said second panel.

16. The charging device that receives light from diverse sources according to claim 12, further including a connector that joins said charging circuit module.

17. The charging device that receives light from diverse sources according to claim 12, further including an electricity storage element connected with said charging circuit module to store electricity provided by said charging circuit module.

18. The charging device that receives light from diverse sources according to claim 16, further including an electricity storage element connected with said charging circuit module to store electricity provided by said charging circuit module.

19. The charging device that receives light from diverse sources according to claim 12, wherein said main body is a trapezoid base whose four surfaces are disposed with a plurality of cells comprised in said DSSC module; and wherein said charging base is set on the flat of said trapezoid base.

20. The charging device that receives light from diverse sources according to claim 19, wherein a pyramid is set on said trapezoid base to form a larger pyramid and pivots on it through a pivotal structure.

21. The charging device that receives light from diverse sources according to claim 19, further including an electricity storage element connected with said charging circuit module to store electricity provided by said charging circuit module.

22. The charging device that receives light from diverse sources according to claim 12, wherein said main body is a table with a tabletop on which said DSSC module is disposed.

23. The charging device that receives light from diverse sources according to claim 22, wherein said tabletop is a DSSC.

24. The charging device that receives light from diverse sources according to claim 22, further including an electricity storage element connected with said charging circuit module to store electricity provided by said charging circuit module.
